(19) United States
(12) Patent Application Publication
(10) Pub. No.: US 2012/0306022 A1
(43) Pub. Date: Dec. 6, 2012

(54) Metal oxide semiconductor transistor layout with higher effective channel width and higher component density

(76) Inventors: Chia-So CHUAN, Hsichu City (TW); Yi-Hsien Lai, Kaohsiung City (TW); Mei-Chen Wu, Hsichu City (TW)

(21) Appl. No.: 13/118,695

(22) Filed: May 31, 2011

(51) Int. Cl. H01L 27/088

(52) U.S. Cl. 257/390; 257/E27.06

(57) ABSTRACT

The disclosure is a metal oxide semiconductor transistor layout with higher effective channel width and higher component density. The layout discloses a common drain region with straight cross pattern, a plurality of common drain regions with lattice pattern, a common source region with straight cross pattern, a plurality of common source regions with lattice pattern, a hybrid grating with common drain region with straight cross pattern and common source region with straight cross pattern. The layout can increase the component density and the effective channel width as compared to conventional layout. The invention is further with the advantages of lower cost and can be operated in higher power.

### BACKGROUND OF THE INVENTION

1. Field of the invention

The present invention generally relates to a metal oxide semiconductor transistor layout, and more particularly to a metal oxide semiconductor transistor layout with higher effective channel width and higher component density. The layout of present invention can increase the component density and provide the wider and longer effective channel width and length as compared to conventional layout. The invention is further with the advantages of lower cost and can be operated in higher power.

2. Description of the Related Art

In recent years, the dimensions of metal oxide semiconductor (MOS) transistor device are reduced to achieve the purpose of increasing the component speed and drive current. However, according to ITRS roadmap, using the component size reducing method to increase the component speed is approaching the limit. Therefore, it is more and more difficult to improve the performance by reducing component size.

Furthermore, a large line-width of metal oxide semiconductor transistors (Power MOS) is also widely applied as power management applications of the power switch. However, the source and drain of such a metal oxide semiconductor transistor with the long connecting wire will cause some defects or problems, such as wiring a serious voltage drop. In addition, taking into account the degree of product sets of factors, the lattice space of power components must be as small as possible. Thus, the metal connecting wire width of metal oxide semiconductor transistor source and drain will be limited. According to the electron migration problem, the metal connection wire length of source and drain is limited, especially when the connected metal wire width is limited. So, the traditional high-power metal oxide semiconductor transistor is difficult to have both high current capabilities and high degree layout.

U.S. Pat. No. 7,132,717 entitled “Power Metal Oxide Semiconductor Transistor Layout with Lower Output Resistance and High Current Limit”, discloses that a power metal oxide semiconductor transistor layout, and more particularly to a wire connected in mesh or in a plane. However, the source/drain wires connected in the case does not clearly reveal its rules of electrostatic discharge (ESD) protection layout.

Referring to FIG. 1(A), it shows the learning technology of metal oxide semiconductor transistor layout 100 with metal oxide semiconductor transistor layout array 110. It comprises source 120, drain 130, gate 140, transistor 150, source connected wire 160, and drain connected wire 170.

Referring to FIG. 1(B), it shows the source drain connection diagram of learning technology of metal oxide semiconductor transistor layout with slash connection which connects source connected wire 160 and drain connected wire 170. In general, it has the problems in (1) whether the corner of source and drain is connected smoothly, (2) asymmetric connection circuit. Therefore, it is necessary to propose a metal oxide semiconductor transistor layout with higher effective channel width and higher component density in order to solve the forementioned problems.

### BRIEF SUMMARY OF THE INVENTION

It is an objective of the present invention to provide a metal oxide semiconductor transistor layout which can be used in standard CMOS process and provides higher effective channel width and higher component density.

To achieve the above objective, the present invention provides a metal oxide semiconductor transistor layout with higher effective channel width and higher component density, comprising a substrate, a common drain area with cross pattern, a plurality of common source areas with lattice pattern, a common source area with cross pattern, a plurality of common drain areas with lattice pattern, a plurality of common gate areas with lattice pattern, where the common drain area with cross pattern and formed on the substrate, the plurality of common source areas with lattice pattern are allocated on four corners of the common drain area with cross pattern and formed on the substrate, the common source area with cross pattern is formed on the substrate, the plurality of common drain areas with lattice pattern are allocated on four corners of the common drain with cross pattern and formed on the substrate, the plurality of common gate areas are allocated among the common drain area with cross pattern and the plurality of common source areas with lattice pattern, the common source area with cross pattern and the plurality of common drain areas with lattice pattern, and the plurality of common drain areas with lattice pattern and the plurality of common source areas with lattice pattern and formed on the substrate.

According to one aspect of the present invention, the substrate can be replaced and selected from the sapphire substrate, silicon substrate, Gallium arsenide substrate, silicon-on-insulator (SOI) substrate, silicon germanium substrate and glass substrate.

According to one aspect of the present invention, the lattice pattern can be replaced and selected from rectangular, square and rhombus.

According to one aspect of the present invention, the grid area of common drain area with cross pattern is allocated between any two adjacent the grid areas of the common source area with cross pattern and thereby forms a hybrid array of common drain area with cross pattern and the common source area with cross pattern.

According to one aspect of the present invention, the plurality of common gate areas are allocated between the grid area of common drain area with cross pattern and the grid area of common source area with cross pattern.

According to one aspect of the present invention, the hybrid array of common drain area with cross pattern and common source with cross pattern can be implemented by one of the standard CMOS process of 0.35 μm, 0.25 μm, 0.18 μm, 0.13 μm, 90 μm, 45 μm or advanced process.

According to one aspect of the present invention, the common drain area with cross pattern and the plurality of common drain areas with lattice pattern, and each of the plurality of common drain areas with lattice pattern included respectively by any two adjacent grid area of common drain area with cross pattern and the grid area of common source area with cross pattern are connected via a first meshed wire.

According to one aspect of the present invention, the common source area with cross pattern and the plurality of common source areas with lattice pattern, and each of the plurality of common source areas with lattice pattern included respectively by any two adjacent grid area of common drain area with cross pattern and the grid area of common source area with cross pattern are connected via a second meshed wire.

These and many other advantages and features of the present invention will be readily apparent to those skilled in the art from the following drawings and detailed descriptions.

### BRIEF DESCRIPTION OF THE DRAWINGS

All the objects, advantages, and novel features of the invention will become more apparent from the following detailed description when taken in conjunction with the accompanying drawing.

FIG. 1(A) shows the metal oxide semiconductor transistor layout of the prior art;

FIG. 1(B) shows the connected configuration of source-drain of metal oxide semiconductor transistor layout of the prior art;

FIG. 2(A) shows the metal oxide semiconductor transistor layout with higher effective channel width and higher component density of the present invention;

FIG. 2(B) shows the connected configuration of drain areas of metal oxide semiconductor transistor layout of the present invention; and

FIG. 2(C) shows the connected configuration of source areas of metal oxide semiconductor transistor layout of the present invention.

### DETAILED DESCRIPTION OF THE INVENTION

Although the invention has been explained in relation to several preferred embodiments, the accompanying drawings and the following detailed descriptions are the preferred embodiment of the present invention. It is to be understood that the following disclosed descriptions will be examples of present invention, and will not limit the present invention into the drawings and the special embodiment.

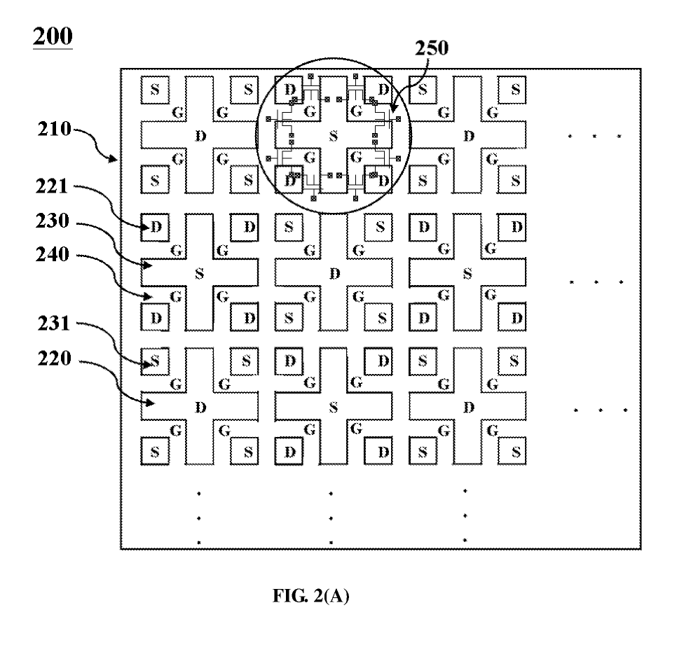

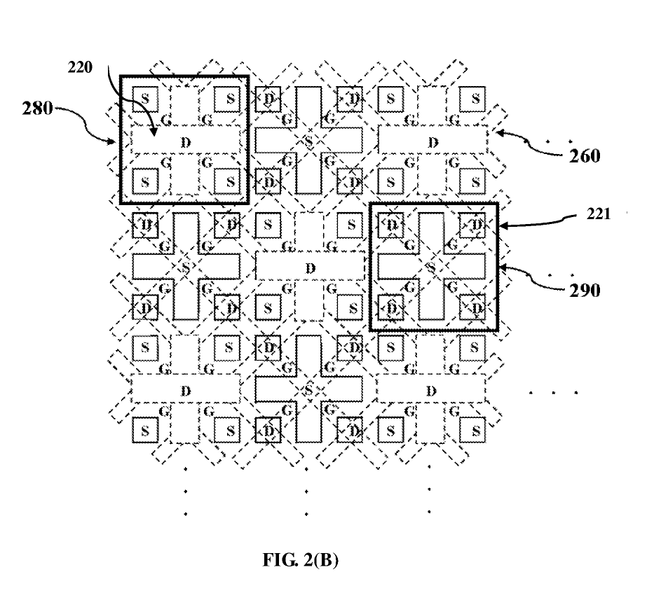

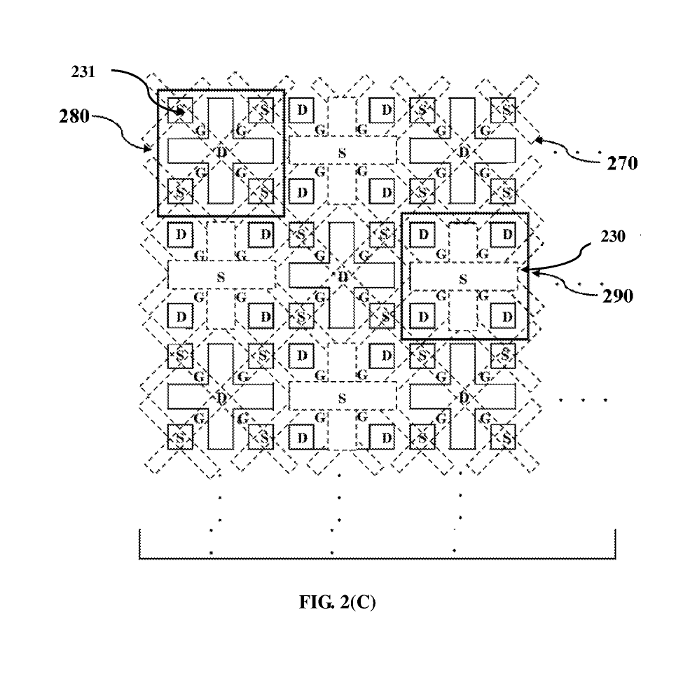

To understand the spirit of the present invention, please referring to FIG. 2(A), it shows the metal oxide semiconductor transistor layout with higher effective channel width and higher component density of the present invention, wherein the layout 200 comprises: a substrate, a common drain area with cross pattern 220, a plurality of common source areas with lattice pattern 231, a common source area with cross pattern 230, a plurality of common drain areas with lattice pattern 221 and a plurality of common gate areas with lattice pattern 240. The common drain with cross pattern 220 is formed on the substrate. The plurality of common source areas with lattice pattern 231 are allocated on four corners of the common drain area with cross pattern 220 and formed on the substrate. The common source area with cross pattern 220 is formed on the substrate. The plurality of common drain areas with lattice pattern 221 are allocated on four corners of the common drain with cross pattern 220 and formed on the substrate. The plurality of common gate 240 which is allocated in the common drain with cross pattern 220 and the plurality of common source with lattice pattern 231, the common source with cross pattern 230 and the plurality of common drain with lattice pattern 221, and the plurality of common drain with lattice pattern 221 and the plurality of common source with lattice pattern 231 is formed on the substrate. The lattice pattern can be replaced and selected from rectangular, square and rhombus.

It should to be noted that the common drain area with cross pattern 220, the plurality of common source areas with lattice pattern 231 and the plurality of common gate areas 240 can form the grid area of common drain areas with cross pattern 280. The common source area with cross pattern 230, the plurality of common drain areas with lattice pattern 221 and the plurality of common gate areas 240 can form the grid area of common source area with cross pattern 290. The grid area of common drain area with cross pattern 280 is allocated between any two adjacent the grid areas of the common source area with cross pattern 290 and thereby forms a hybrid array of common drain area with cross pattern 210 and the common source area with cross pattern. Moreover, the plurality of common gate areas 240 are between the grid area of common drain area with cross pattern 280 and the grid areas of the common source area with cross pattern 290.

In general, the metal oxide semiconductor transistor layout 200 with higher effective channel width and higher component density of the present invention can be realized and implemented on the sapphire substrate, silicon substrate, gallium arsenide substrate, the silicon-on-insulator (SOI) substrate, silicon germanium substrates and glass substrates. The hybrid array of the common drain with cross pattern 210 and the common source area with cross pattern can be implemented by one of the standard CMOS process of 0.35 μm, 0.25 μm, 0.18 μm, 0.13 μm, 90 μm, 45 μm or advanced process.

Now please referring to FIG. 2(B), it shows the connected configuration of drain areas of metal oxide semiconductor transistor layout of the present invention, wherein the common drain area with cross pattern 220 and the plurality of common drain areas with lattice pattern 221, and each of the plurality of common drain areas with lattice pattern 221 included respectively by any two adjacent grid area of common drain area with cross pattern 280 and the grid area of common source area with cross pattern 290 are connected via a first meshed wire 260.

Referring to FIG. 2(C), it shows the connected configuration of source areas of metal oxide semiconductor transistor layout of the present invention, wherein the common source area with cross pattern 230 and the plurality of common source areas with lattice pattern 231, and each of the plurality of common source areas with lattice pattern 231 included respectively by any two adjacent grid area of common drain area with cross pattern 280 and the grid area of common source area with cross pattern are connected 290 via a second meshed wire 270. In general, the first meshed wire 260 and the second meshed wire 270 are used to be the copper here, that is, the metal oxide semiconductor transistors with higher effective channel width and higher component density of the present invention are all connected in parallel.

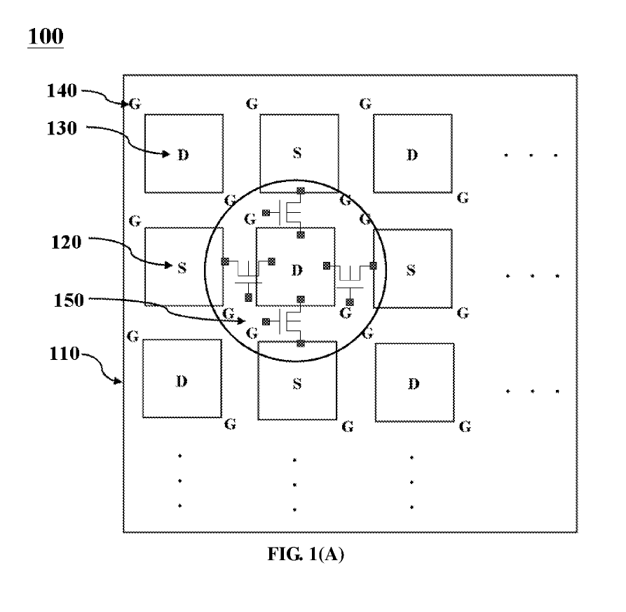

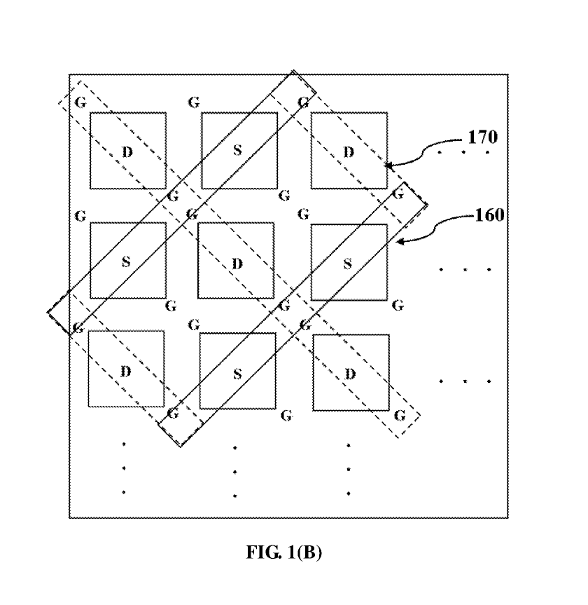

Now please referring to FIG. 1(A) and FIG. 2(A) again, the number of transistors 150 and transistors 250 which are corresponding to the FIG. 1(A) and FIG. 2(A), respectively, the using of hybrid arrays of the common drain with cross pattern and the common source with cross pattern 210 can provide one time density of transistor under every unit square.

In the embodiment, if the common drain area with cross pattern and the common source area with cross pattern 210 is a 3×3 array, that is, containing 5 groups of grid areas of common source area with cross pattern 290 and 4 groups of grid areas of common drain area with cross pattern 280. The number of metal oxide semiconductor transistors of the present invention is up to 72.

In summary, the metal oxide semiconductor transistor layout with higher effective channel width and higher component density of the present invention has the following advantages of:
1. By using the common drain area with cross pattern and the plurality of common drain areas with lattice pattern, the hybrid arrays of the common drain area with cross pattern formed by the common source area with cross pattern and the plurality of common source areas with lattice pattern and the common source area with cross pattern, it can increase the density of transistor as compared with traditional circuit layout and further provide the wider and longer effective channel width and length, which can achieve the purpose of lower cost and higher power operation.
2. As compared with the traditional circuit layout, the number of transistors can be doubled under the same area.

Although the invention has been explained in relation to its preferred embodiment, it is not used to limit the invention. It is to be understood that many other possible modifications and variations can be made by those skilled in the art without departing from the spirit and scope of the invention as hereinafter claimed.

What is claimed is:

1. A metal oxide semiconductor transistor layout with higher effective channel width and higher component density, comprising:
a substrate;
a common drain area with cross pattern, formed on the substrate;
a plurality of common source areas with lattice pattern, allocated on four corners of the common drain area with cross pattern and formed on the substrate;
a common source area with cross pattern, formed on the substrate;
a plurality of common drain areas with lattice pattern, allocated on four corners of the common drain area with cross pattern and formed on the substrate; and
a plurality of common gate areas, allocated among the common drain area with cross pattern and the plurality of common source areas with lattice pattern, the common source area with cross pattern and the plurality of common drain areas with lattice pattern, and the plurality of common drain areas with lattice pattern and the plurality of common source areas with lattice pattern and formed on the substrate;
wherein the common drain area with cross pattern, the plurality of common source areas with lattice pattern and the plurality of common gate areas can form a grid area of common drain area with cross pattern; and wherein the common source area with cross pattern, the plurality of common drain areas with lattice pattern and the plurality of common gate areas can form a grid area of common source with cross pattern.

2. A metal oxide semiconductor transistor layout with higher effective channel width and higher component density as claimed in claim 1, wherein the substrate can be replaced and selected from the sapphire substrate, silicon substrate, gallium arsenide substrate, silicon-on-insulator (SOI) substrate, silicon germanium substrate and glass substrate.

3. A metal oxide semiconductor transistor layout with higher effective channel width and higher component density as claimed in claim 1, wherein the lattice pattern can be replaced and selected from rectangular, square and rhombus.

4. A metal oxide semiconductor transistor layout with higher effective channel width and higher component density as claimed in claim 1, wherein the grid area of common drain area with cross pattern is allocated between any two adjacent the grid areas of the common source area with cross pattern and thereby forms a hybrid array of common drain area with cross pattern and the common source area with cross pattern.

5. A metal oxide semiconductor transistor layout with higher effective channel width and higher component density as claimed in claim 1, wherein the plurality of common gate areas are allocated between the grid area of common drain area with cross pattern and the grid area of common source area with cross pattern.

6. A metal oxide semiconductor transistor layout with higher effective channel width and higher component density as claimed in claim 5, wherein the hybrid array of common drain area with cross pattern and common source with cross pattern can be implemented by one of the standard CMOS process of 0.35 μm, 0.25 μm, 0.18 μm, 0.13 μm, 90 μm, 45 μm or advanced process.

7. A metal oxide semiconductor transistor layout with higher effective channel width and higher component density as claimed in claim 1, wherein the common drain area with cross pattern and the plurality of common drain areas with lattice pattern, and each of the plurality of common drain areas with lattice pattern included respectively by any two adjacent grid area of common drain area with cross pattern and the grid area of common source area with cross pattern are connected via a first meshed wire.

8. A metal oxide semiconductor transistor layout with higher effective channel width and higher component density as claimed in claim 1, wherein the common source area with cross pattern and the plurality of common source areas with lattice pattern, and each of the plurality of common source areas with lattice pattern included respectively by any two adjacent grid area of common drain area with cross pattern and the grid area of common source area with cross pattern are connected via a second meshed wire.
